(19) United States
(12) Patent Application Publication
(10) Pub. No.: US 2012/0187264 A1
(43) Pub. Date: Jul. 26, 2012

(54) DISPLAY MOUNT FOR CORNER INSTALLATIONS

(76) Inventor: Michael Vlies, Lake Forest, IL (US)

(21) Appl. No.: 13/354,063

(22) Filed: Jan. 19, 2012

Related U.S. Application Data
(63) Continuation-in-part of application No. 12/587,754, filed on Oct. 13, 2009, now Pat. No. 8,100,372.
(60) Provisional application No. 61/195,832, filed on Oct. 10, 2008.

(51) Int. Cl. H05K 7/00

(52) U.S. Cl. 248/220.1

(57) ABSTRACT

The invention provides a corner mount system for mounting a flat screen display at a corner seam within a corner region in order to efficiently utilizes space within that region. The corner mount system comprises a corner bracket with a right plate and a left plate, each having a side rail that provides a channel, wherein the channels collectively define a receiver. Each plate includes at least one hole for reception of a fastener to secure the corner bracket to the studs at behind the wall at the corner seam. The corner mount system further includes an elongated interface member which is slidingly engaged and secured by the corner bracket. A support arm assembly includes a connector, a first arm and a flat screen display bracket. The bracket is removably connected to the flat screen display and the connector is secured to the interface member.

### CROSS-REFERENCE TO RELATED APPLICATIONS

Pursuant to 35 U.S.C. 120, this continuation-in-part application claims priority from pending U.S. patent application Ser. No. 12/587,754, filed Oct. 13, 2009, which claims priority under 35 U.S.C. 119 from U.S. Provisional Application No. 61/195,832, filed Oct. 10, 2008, which applications are incorporated herein by reference and made a part hereto.

### FEDERALLY SPONSORED RESEARCH OR DEVELOPMENT

Not applicable.

### TECHNICAL FIELD

The invention relates to a corner mount system for installing a flat screen monitor or display to a corner region. The novel corner mount system permits installation deep within a corner region, flush with the seam that defines the corner, thereby eliminating the need for wall securement a distance away from the corner.

### BACKGROUND OF THE INVENTION

Flat panel displays and monitors, such as plasma, LED and LCD televisions, are an increasingly popular substitute for projection televisions and “tube” televisions. A mount apparatus can be used to secure the flat panel display to an elevated position on a wall. The clarity and resolution of flat panel displays, are typically best from a position directly in front of the display. As a result, most consumers use existing mounts to secure the flat panel display in the middle of the wall. For example, the existing mount includes a large plate that is secured to the wall in front of a couch to minimize any offset viewing angle. This mounting convention can be found in a number of retail and commercial usages, for example in restaurants and bars, where multiple flat panel displays are mounted across the wall opposite the seating area to allow for patron viewing. The display image is often too dark or not visible if viewed from a significant angle. Thus, it is quite uncommon to find a flat panel display mounted to a corner of the wall, even when the corner provides for the most efficient use of space.

Conventional mounts necessitate installation to an intermediate portion of the support wall, i.e. a distance from the corners, because conventional mount designs include large components, such as plate(s), that create clearance issues and preclude installation within the close confines of a corner. However, before a flat screen display is mounted to the wall, at least one stud, and typically a plurality of studs, must be located. Because flat screen displays tend to be heavy, the mount must be mounted to a stud behind the wall for proper support. Conventional mounts that are adaptable for corner installation suffer from a number of limitations, including bulky, complicated or poorly functioning adaptor kits and/or hardware that dramatically limit the functionality and effectiveness of the mount, and which preclude installation deep within a corner region. As a result, conventional mounts consume too much use of wall space and preclude the efficient usage of wall space.

The present invention seeks to overcome certain of these limitations and other drawbacks of the prior art, and to provide new features not heretofore available. A full discussion of the features and advantages of the present invention is deferred to the following detailed description, which proceeds with reference to the accompanying drawings.

### SUMMARY OF THE INVENTION

The present invention is directed to a corner mount system that is suitable for installing a flat screen display deep within a corner region in either a left-wall or right-wall installation. The corner mount system includes a wall bracket having a first side edge and a second side edge. A first angled surface extends at an angle from the first side edge, and it includes at least one opening. The wall bracket also has a securing region with at least one hole.

The corner mount system further includes an interface member. The interface member has a tapered opening defined by opposed flanges. The interface member has an aperture that is aligned with the opening of the first angled surface of the wall bracket. A fastener is received by the aperture and the opening to couple the interface member to the wall bracket. The corner mount system also includes a support arm assembly for supporting the flat screen display. The support arm assembly includes a connector, a first arm and a flat screen display bracket. The connector is slidably received by the tapered opening of the interface member to couple the support arm assembly to the interface member and wall bracket.

According to another aspect of the invention, the corner mount system comprises a corner bracket having a right plate and a left plate which intersect to form an edge. Each of the right and left plates includes a side rail, and each side rail provides a channel, wherein the channels define a receiver. The corner bracket includes at least one hole for reception of a fastener to secure the corner bracket to the studs behind the wall at the seam of the corner region. The corner mount system further includes an elongated interface plate which is slidably receivable by the receiver of the corner bracket. A support arm assembly is provided which includes a connector, a first arm and a flat screen display bracket. The connector is joined to the interface member to couple the support arm assembly to the interface member. Once the bracket is connected to the flat screen display the resulting combination is coupled to the corner bracket by reception of the interface member by the receiver.

Other features and advantages of the invention will be apparent from the following specification taken in conjunction with the following drawings.

### BRIEF DESCRIPTION OF THE DRAWINGS

To understand the present invention, it will now be described by way of example, with reference to the accompanying drawings in which:

FIG. 1 is a perspective view of a corner mount system having a wall bracket, an interface member and a pivotal support arm assembly in a left installation;

FIG. 2 is a partially exploded view of the corner mount system showing the interface member and the pivotal support arm assembly;

FIG. 3 is a perspective view of a second installation embodiment of a corner mount system having a wall bracket and a pivotal support assembly in a left installation;

FIG. 4 is a perspective view of the corner mount apparatus of FIG. 3 in a right installation;

FIG. 5 is a perspective view of the wall bracket;

FIG. 6 is a perspective view of the wall bracket of the corner mount system in a left installation;

FIG. 7 is a perspective view of the wall bracket of the corner mount system in a right installation;

FIG. 8 is a perspective view of the wall bracket of the corner mount system;

FIG. 9 is a perspective view of an alternate wall bracket of a corner mount system; and

FIG. 10 is a perspective view of a second corner mount system of the invention in an installed position;

FIG. 11 is a perspective view of the interface plate and corner bracket of the corner mount system of FIG. 10;

FIG. 12 is a front view of the interface plate and corner bracket of the corner mount system of FIG. 10;

FIG. 13 is an exploded view of the interface plate, corner bracket and a securing member of the corner mount system of FIG. 10;

FIG. 14 is a front view of the interface plate of the corner mount system of FIG. 10;

FIG. 15 is a front view of the corner bracket of the corner mount system of FIG. 10;

FIG. 16 is a top view of the corner mount system of FIG. 10 in the installed position;

FIG. 17 is a cross-sectional view of the corner mount system of FIG. 10 in the installed position, taken along line 17-17 of FIG. 16; and

FIG. 18 is a cross-sectional view of the corner mount system of FIG. 10 in a partially installed position, taken along line 17-17 of FIG. 16.

### DETAILED DESCRIPTION

While this invention is susceptible of embodiments in many different forms, there are shown in the drawings and will herein be described in detail preferred embodiments of the invention with the understanding that the present disclosure is to be considered as an exemplification of the principles of the invention and is not intended to limit the broad aspect of the invention to the embodiments illustrated.

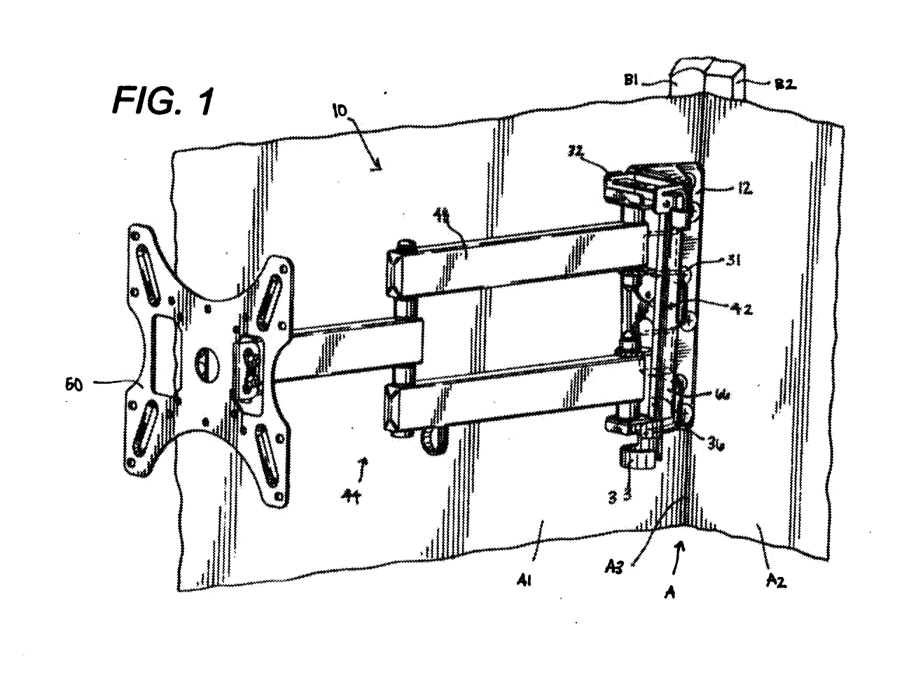

FIG. 1 shows a corner mount system 10 that is suitable for installing a flat screen display (not shown) within a corner region A in either a left-wall or right-wall installation position. Unlike conventional mounts, the corner mount system 10 can be installed deep within the corner region A, on either the left wall A1 or the right wall A2. As such, the corner mount system 10 can be installed proximate a corner seam A3, located at the intersection of the left and right walls A1, A2, to minimize the unnecessary consumption of wall space. These attributes increase the versatility of the corner mount system 10, especially compared to conventional mounts which include structures and/or components that preclude an adequate corner installation due to their significant bulk and dimensions. The limitations of conventional mounts are exacerbated when a flat screen monitor is joined to the mount, thereby making the mount and monitor combination even bulkier, and precluding a corner installation.

Further, mounting the corner mount system 10 proximate the corner seam A3 ensures that the corner mount system 10 will be mounted to a stud. As shown in FIG. 1, studs B1 and B2 are located behind the left and right walls A1, A2, respectively. Generally, structures such as houses or commercial buildings are built such that their corner regions are formed by at least two studs. Therefore, installing the corner mount system 10 in a corner region A proximate the corner seam A3 ensures that the corner mount system 10 will be mounted on either the left stud B1 or the right stud B2, which will provide adequate support for the load resulting from a connection of the flat screen display.

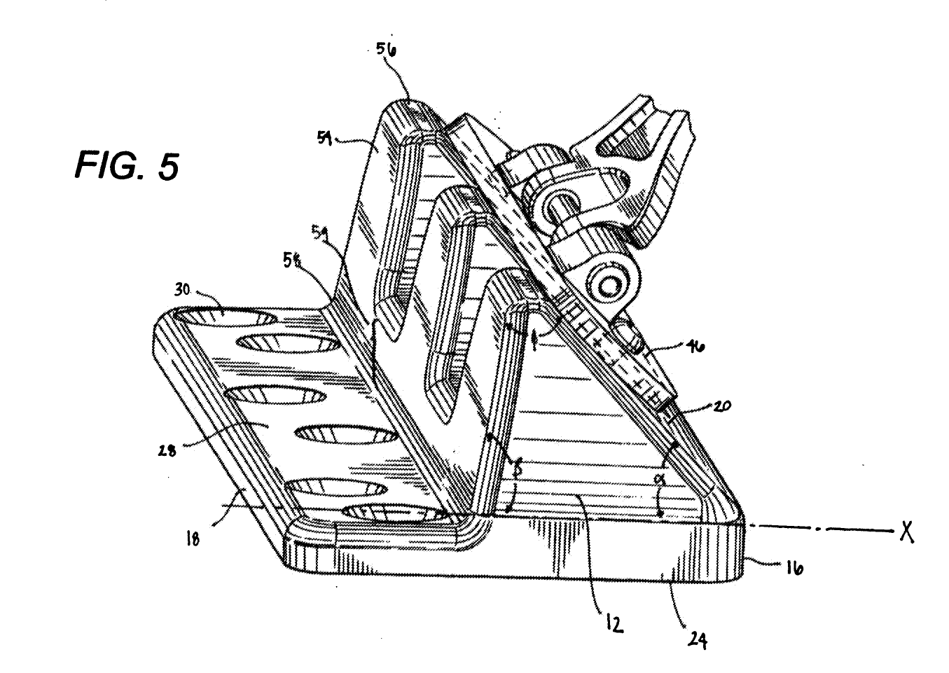

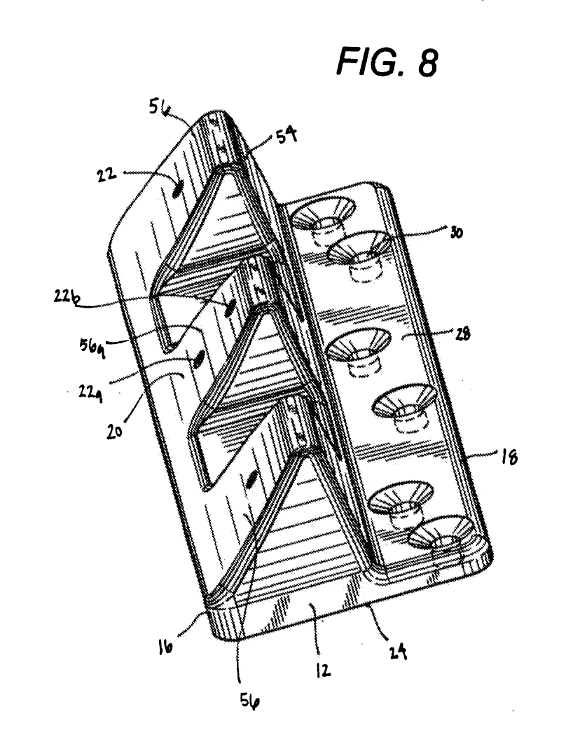

The corner mount system 10 generally includes a wall bracket 12 and a support arm assembly 44. In one embodiment, shown in FIG. 1, the corner mount system 10 may also include an interface member 32. The wall bracket 12 includes a first side edge 16, a second side edge 18 and a first angled surface 20. (See FIGS. 5 and 8). The first angled surface 20 includes at least one opening 22, which can also be seen in FIG. 8. The first angled surface 20 extends at an angle α from the first side edge 16, which is measured with respect to a horizontal reference line X, which is substantially parallel to a first end 24 of the wall bracket 12. The first angled surface 20 extends at an acute angle α, between 40 and 60 degrees, preferably at an angle between 45 and 55 degrees, and most preferably at 50 degrees.

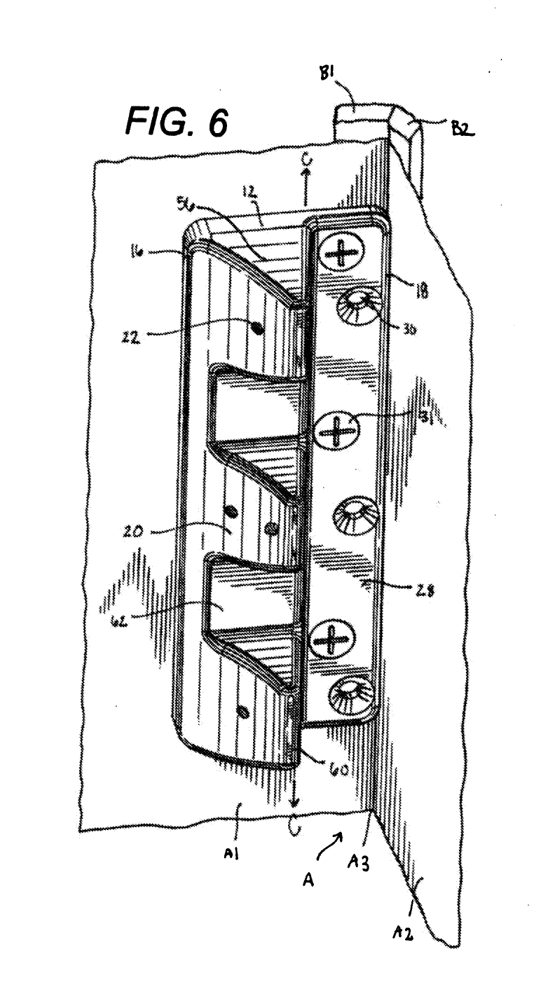

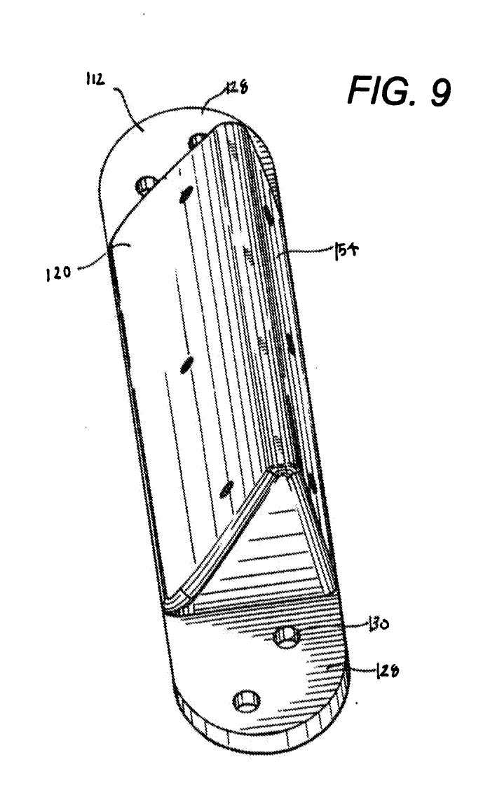

The wall bracket 12 further includes a securing region 28 which has at least one hole 30. As shown in FIG. 6, the wall bracket 12 may be mounted to a wall by inserting a fastener 31, such as a flat head screw, into the hole 30, arranged in pairings, of the wall bracket 12. FIG. 6 also shows that the securing region 28 may include a plurality of holes 30 which facilitate installation to the left or right walls A1, A2. In another embodiment, shown in FIG. 9, a wall bracket 112 may multiple securing regions 128, wherein the securing regions 28 are located at opposed ends of the wall bracket 112. In this embodiment, the securing regions 128 may include at least one hole 130 for receiving a fastener 131, or they may include a plurality of holes 130. The wall bracket 112 may also include a first angled surface 120 and a second angled surface 154.

The corner mount system 10 further includes the interface member 32, which is shown in FIG. 1. The interface member 32 includes a tapered opening 34 which is defined by opposed flanges 36, 38. The flanges 36, 38 may be positioned on sidewalls 66, 68 of the interface member 32. The sidewalls 66, 68 may be angled in order to form the tapered opening 34. The interface member 32 includes at least one aperture 40 that can be aligned with the opening 22 of the first angled surface 20. The opening 22 and aperture 40 receives a fastener 42 which couples the interface member 32 to the wall bracket 12. The interface member 32 also includes a cord retention element 33.

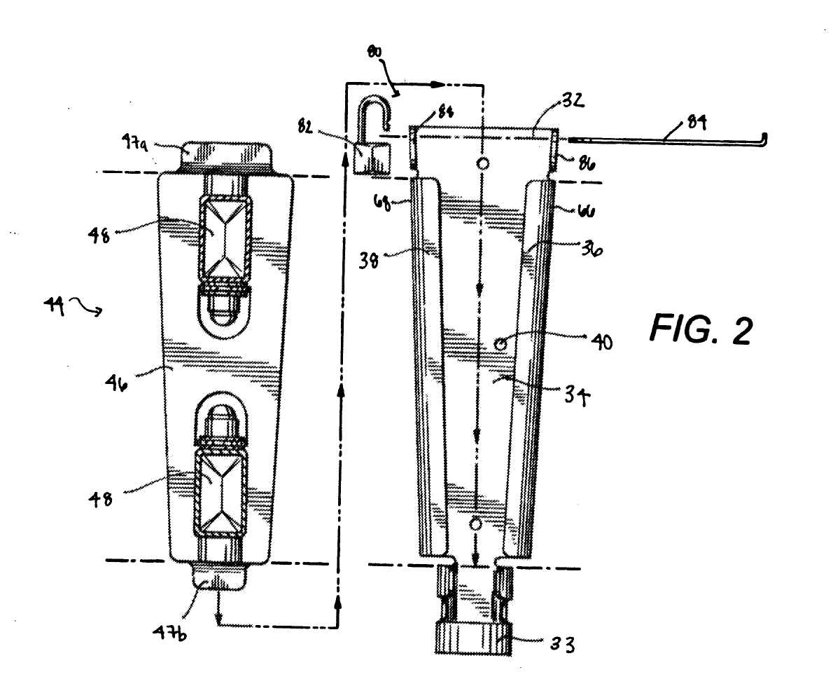

As shown in FIG. 1, the corner mount system 10 also includes a pivotal support arm assembly 44. The support arm assembly 44 includes a tapered connector 46 for connecting the support arm assembly 44 to the interface member 32. The connector 46 is slidably received by the tapered opening 34 of the interface member 32 to couple the support arm assembly 44 to the interface member 32 and the wall bracket 12. The flanges 36, 38 of the interface member 32 secure the connector 46 of the support arm assembly 44 to the interface member 32. The connector 46 includes an upper tab 47a and a lower tab 47b that reside between the flanges 3, 38 when the connector is received by the tapered opening 34. The support arm assembly 44 further includes at least one arm 48 operably joined to the connector 46 to permit movement of the support arm assembly 44 relative to both the connector 46 and the wall bracket 12. The support arm assembly 44 includes a flat screen display bracket 50 for connection to the flat screen display (not shown), wherein the bracket 50 is joined to the arm 48. A locking mechanism 80 is shown in FIGS. 1-2. The locking mechanism 80 includes a lock 82, a bar 84, a first flange 86 and a second flange 88. The components of the locking mechanism 80 interact to prevent undesired or accidental removal of the connector 46 from the tapered opening 34.

In many conventional mounts, an apparatus is attached to a flat screen display, and then that apparatus must be mounted to a wall. This requires one operator to hold the flat screen display up while the apparatus is mounted to the wall by a second operator. This can be an difficult job which may not result in a properly mounted flat screen display. The present invention allows the wall bracket 12 and the interface member 32 to be mounted in the corner region A without the added weight of the flat screen display. Once the wall bracket 12 is mounted to wall A1 or A2, and the interface member 32 is coupled to the wall bracket 12, the flat screen display may be mounted to the bracket 50 of the support arm assembly 44. The support arm assembly 44 may then be secured to the interface member 32 by simply sliding connector 46 into the tapered opening 34 of the interface member 32.

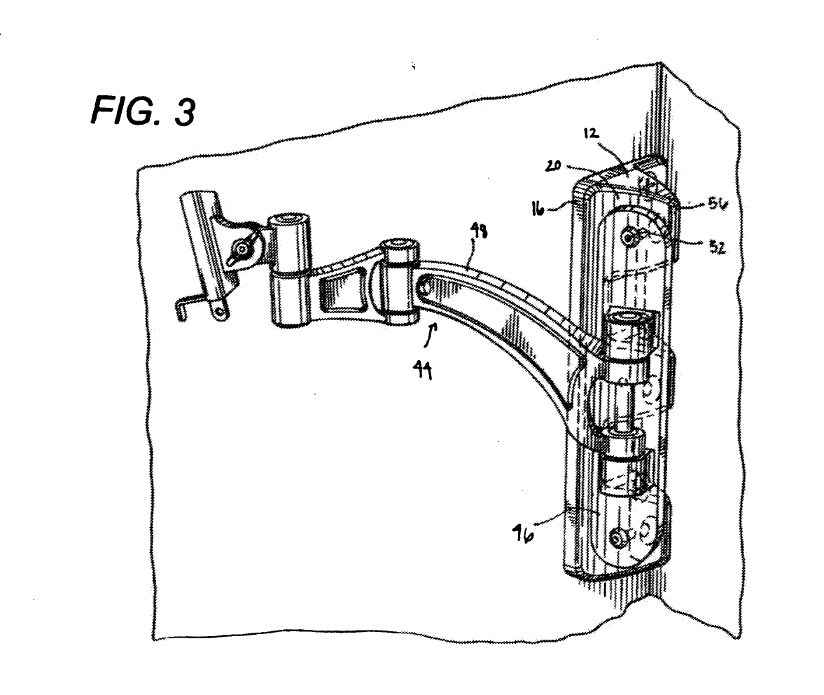

In a second installation embodiment, shown in FIGS. 3-5, support arm assembly 44 may be directly connected to the wall bracket 12, thereby omitting the interface member 32. This may be accomplished by coupling the connector 46 to the first angled surface 20. The connector 46 may include at least one aperture 52 aligned with the opening 22 on the first angled surface 20 to receive a fastener 42 to couple the support arm assembly 44 to the wall bracket 12.

As shown in FIGS. 1-9, the wall bracket 12 may include a second angled surface 54. The second angled surface 54 may converge with the first angled surface 20 such that they form a mounting protrusion 56 on the wall bracket 12. The first and second angled surfaces 20, 54 converge at an angle θ. Angle θ is between 30 and 60 degrees, and preferably between 35 and 50 degrees. In one embodiment, the first and second angled surfaces 20, 54 may be discontinuous such that they provide a series of mounting protrusions 56. As shown in FIG. 8, the first and second angled surfaces 20, 54 may essentially form at least one peak region 60 and one void or valley region 62. As shown in FIGS. 5-8, the second angled surface 54 may be substantially perpendicular with respect to the horizontal reference line X, such that the angle 13 is between 80 and 90 degrees. Preferably, the angle β is between 85 and 90 degrees. This configuration provides the protrusions 56 with a generally triangular cross-section, as seen in FIG. 8. The outermost protrusions 56 have a single opening 22, while the middle protrusion 56a has two openings 22a, 22b, which facilitate connection of the interface member 32 in either the left or right installations.

The second angled surface 54 extends from an intermediate region 58 of the wall bracket 12. In one embodiment, as shown in FIG. 5, the second angled surface 54 is positioned between the first angled surface 20 and securing region 28 of the wall bracket 12. The intermediate region 58 includes a step 59 along an extent of the second angled surface 54 and between the securing region 28 and the valley 62.

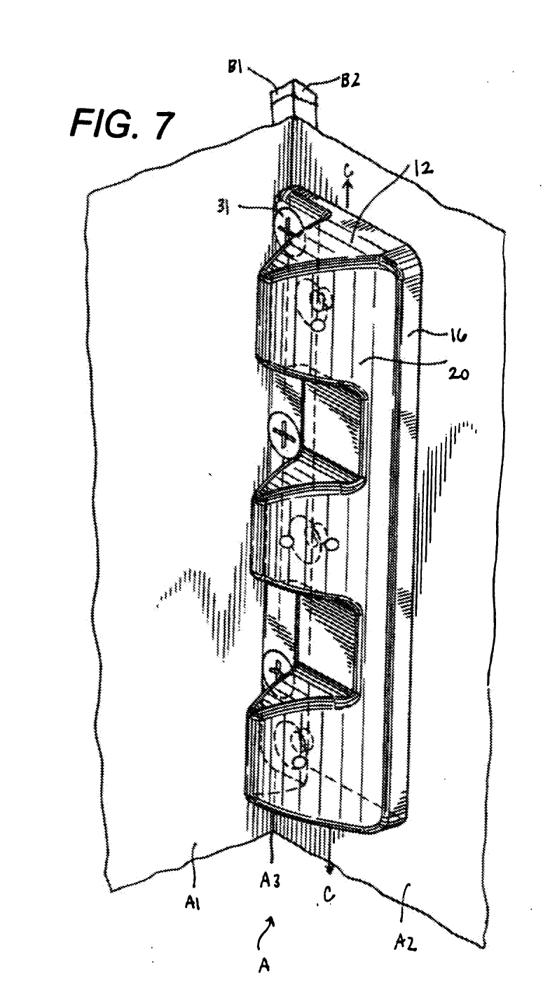

Referring to FIGS. 6 and 7, the corner region A includes left wall A1 and right wall A2. Corner seam A3 is located at the intersection of the walls A1 and A2. FIG. 6 shows a left installation, and FIG. 7 shows a right installation. In FIG. 6, the wall bracket 12 is mounted on the left wall A1 such that the second side edge 18 is proximate the corner seam A3. In this left installation configuration, the first angled surface 20 faces away or outward from the right wall A2, whereas the second angled surface 54 faces toward or into the right wall A2. A plurality of fasteners 31 extend through the holes 30 in the wall bracket 12 and into the wall A1 and the stud B1. From there, the interface member 32 is affixed to the first surface 20. In FIG. 7, the wall bracket 12 is mounted on the right wall A2 such that the second side edge 18 is proximate the corner seam A3. To move the wall bracket from the left installation to the right installation, the wall bracket 12 is rotated 180 degrees and translated until it is positioned such that the second side edge 18 is proximate the corner seam A3. Due to the unique design of the wall bracket 12, it may be located adjacent the corner seam A3.

The rotation of the wall bracket 12 is what allows the second side edge 18 to be proximate the corner seam A3 in both the left wall and right wall installations shown in FIGS. 6 and 7. Further, as mentioned above and shown in FIG. 1, the corner region A of a wall generally comprises at least two studs B1 and B2. The studs are located behind the left and right walls A1, A2 respectively. Thus, positioning the corner mount system 10 in the corner region A such that the second side edge 18 is proximate the corner seam A3 ensures that the wall bracket 12 will be secured to a stud. Unlike conventional mounts, the corner mount system 10 does not need to extend across two studs for securement and only consumes a minimal amount of space on the right or left wall A1, A2. In both the right and left installations a longitudinal axis C-C of wall bracket 12 is substantially parallel to corner seam A3, and studs B1, B2, as shown in FIGS. 6-7.

The corner mount system 10 provides a unique method for installation because the operator can selectively chose the left or right wall A1, A2 for deep installation in the corner region A, namely proximate the seam A3, to maximize the usage of corner region A. Once the operator selects a left wall orientation or a right-wall orientation, the wall bracket 12 is affixed to the respective wall A1, A2 to correspond with the left or right installation positions explained above.

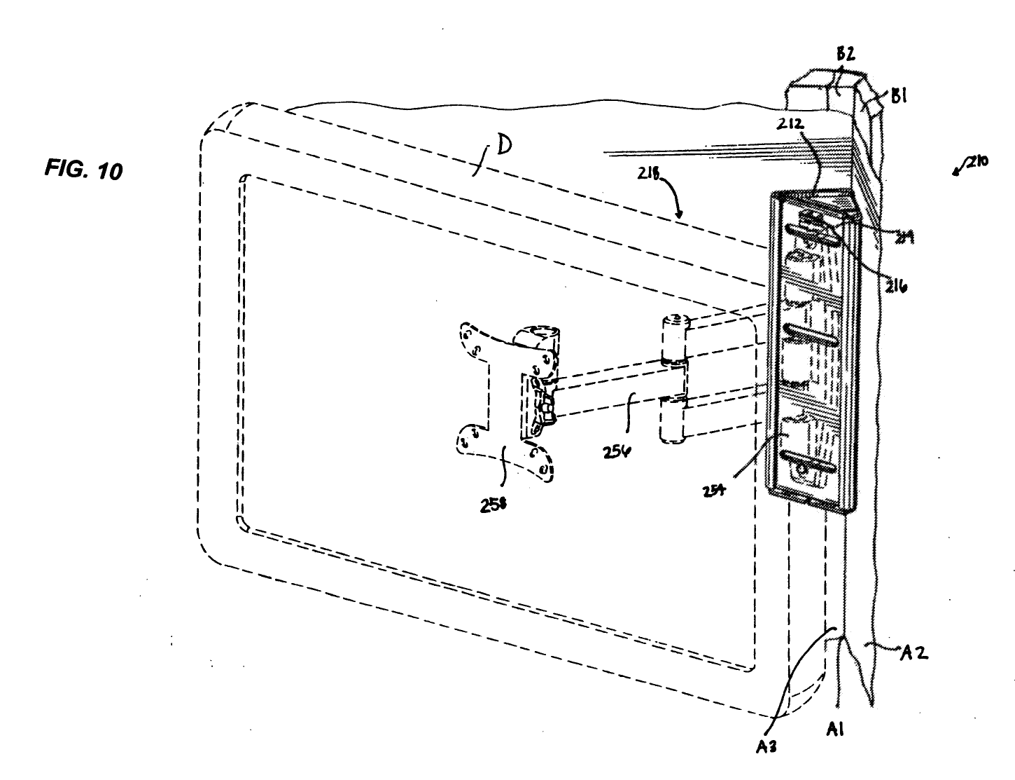

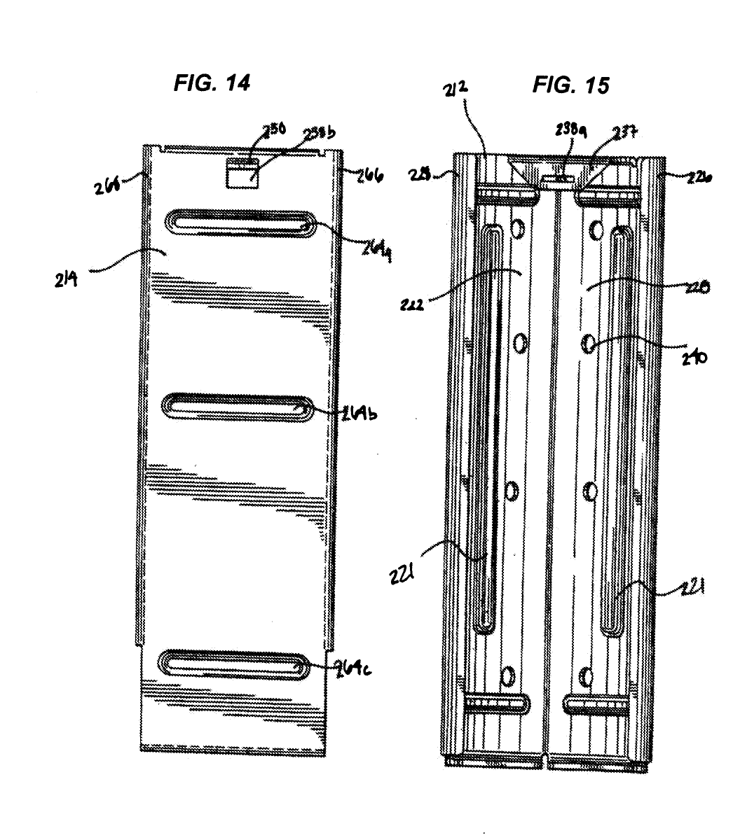

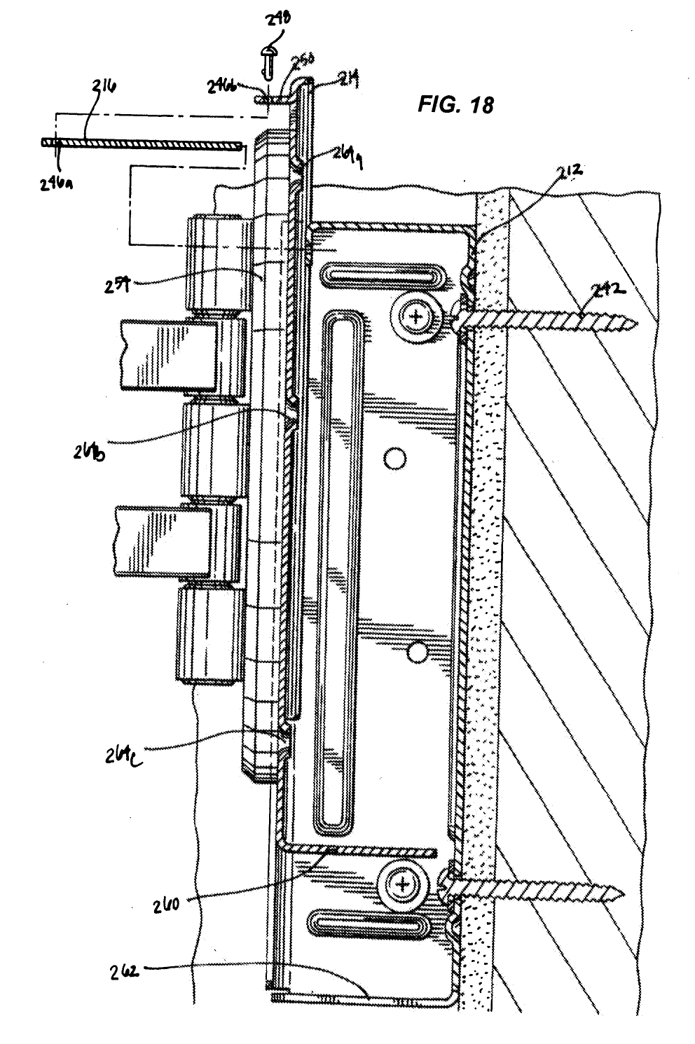

FIGS. 10-18 show a second corner mount system 210 that is suitable for installing a flat screen display D (shown in phantom in FIG. 10), such as a LCD, LED or plasma television or monitor, within a corner region A. Unlike conventional mounts, the corner mount system 210 can be installed deep within the corner region A, such that it is flush with or adjacent to a corner seam A1, formed at the intersection of a right wall A2 and a left wall A3. The seam A1 extends vertically along the height of the corner region A. Consequently, the corner mount system 210 can be installed in a way that minimizes the unnecessary consumption of wall space, which plagues conventional wall mounts. These attributes increase the versatility of the corner mount system 210, especially compared to conventional mounts which include structures and/or components that preclude an adequate corner installation due to their significant bulk and dimensions. The limitations of conventional mounts are exacerbated when a flat screen monitor is joined to the mount, thereby making the mount and monitor combination even larger (i.e., increased width), and precluding a true corner installation. Further, mounting the corner mount system 210 adjacent the corner seam A1 ensures that the corner mount system 210 will be mounted to at least one stud. As shown in FIG. 1, studs B1 and B2 are located behind the right and left walls A2, A3, respectively. Generally, structures such as houses or commercial buildings are built such that their corner regions are formed by at least two studs that are adjacent but oriented 90 degrees from each other. Therefore, installing the corner mount system 210 in a corner region A proximate the corner seam A1 ensures that the corner mount system 210 will be mounted to the right stud B1 and/or the left stud B2, which will provide adequate support for the load resulting from a connection of the flat screen display.

Referring to FIGS. 10-15, the corner mount system 210 generally includes a corner bracket 212, an elongated interface member 214, and a means for securing the corner bracket and the interface member in the installed position. As discussed below, the securing means includes a securing member 216 and a securing tab 236 that interact to prevent upward movement of the interface member relative to the bracket in the installed position. In the embodiment of FIGS. 10-18, the securing means is located at an upper portion of the bracket 212 and interface 214. A pivotal support arm assembly 218 is connectable to both the interface member 214 and the flat screen display D.

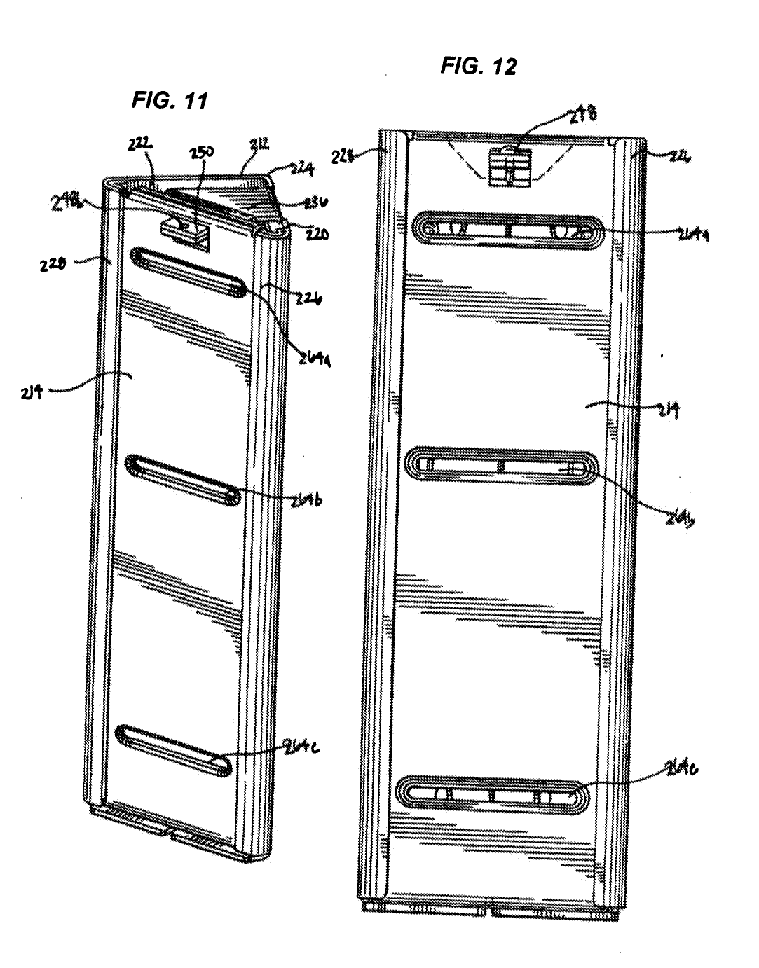

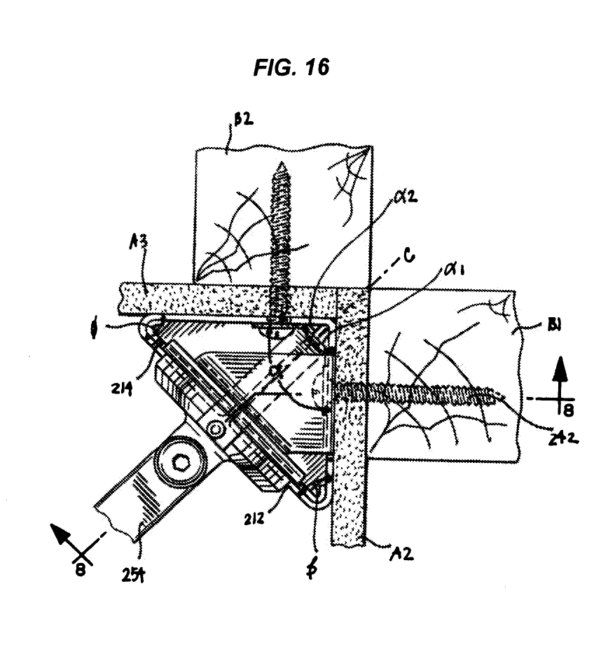

The corner bracket 212 comprises a right plate 220 and a left plate 222, which intersect at a central edge 224 and form an angle α (see FIGS. 3 and 16), which is substantially ninety degrees. Forming angle α at ninety degrees allows for a true corner installation (i.e., the installed position shown in FIG. 10), wherein the right plate 220 is flush with the right wall A2, the left plate 222 is flush with the left wall A3, and the central edge 224 is adjacent the corner seam A1. Also in the installed position, the central edge 224 extends along the corner seam A1. The right plate 220 and left plate 222 may be formed integrally, or separately. The right plate 220 and the left plate 222 each include a side rail 226, 228 with a respective channel 230, 232. Preferably, the side rails 226, 228 and the channels 230, 232 extend along the length of the respective plate 220, 222. Together, the channels 230, 232 define a receiver 234 that engages the interface member 214, as described below. As shown in FIGS. 11-13 and 15, the rails 226, 228 extend a significant extent of, and preferably the length of the plates 220, 222 and are substantially parallel. However the rails 226, 228 may be angled to form a tapered receiver 234, such as a downwardly tapered receiver 234.

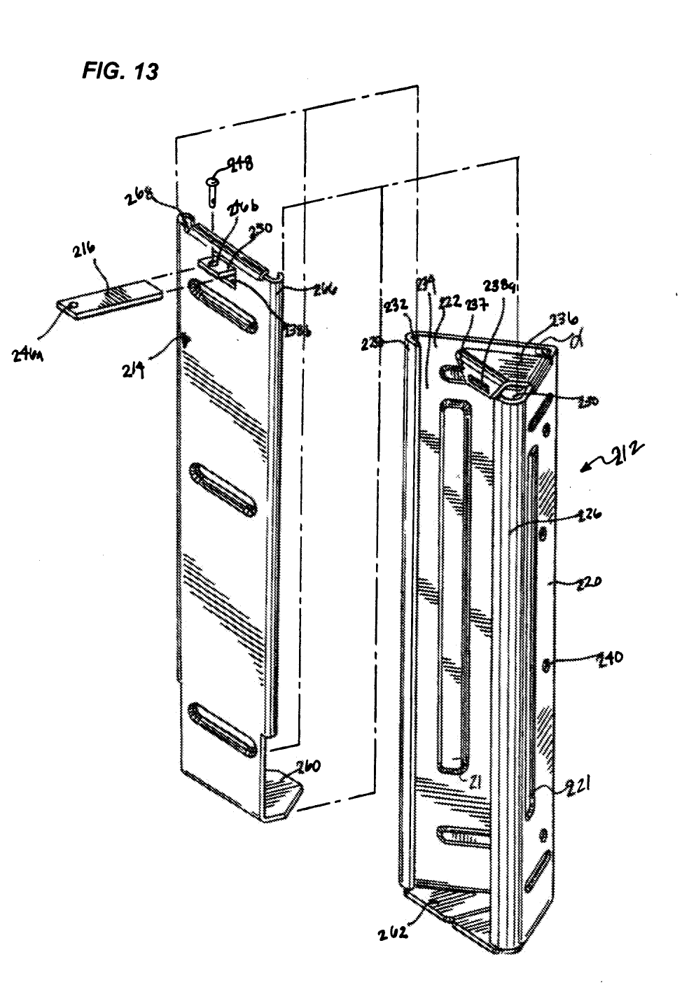

The corner bracket 212 further includes a securing tab 236, which is shown in FIGS. 11-13. The securing tab 236 further includes a lip 237 with a slot 238a. The securing tab 236 is shown as extending perpendicular to the right plate 220. While the securing tab 236 is shown as extending from the right plate 220, the securing tab 236 could alternatively extend from the left plate 222 or from both the right and left plates 220, 222. FIG. 11 shows the securing tab 236 abutting the interface member 214 to further secure the interface member 214 within the receiver 234 of the corner bracket 212. Referring to FIGS. 13 and 15, the corner bracket 212 also includes at least one hole 240 for reception of a fastener 242 to secure the corner bracket 212 to the corner region A. Preferably, both the right and left plates 220, 222 have a plurality of holes 240, which increases the installation flexibility of the bracket 212. As shown in FIGS. 13-16, the right and left plates 220, 222 include a corrugation or deboss 221, preferably oriented longitudinally, that increases the rigidity of the bracket 212.

The interface member 214 is slidably receivable by the receiver 234 of the corner bracket 212. FIG. 13 shows that the interface member 214 has an elongated configuration with a substantially planar central portion 215 between a right side rail 266 and a left side rail 268. As shown, the right and left side rails 266, 268 are curvilinear and cooperatively dimensioned with the side rails 226, 228 of the right and left plates 220, 222. Referring to the partially installed position depicted in FIG. 16, when the interface member 214 is received by the receiver 234, the right and left edges 266, 268 of the interface member 214 slidingly engage the curvilinear side rails 226, 228 of the corner bracket 212. The sliding engagement between these components provides for a secure engagement and retention between the corner bracket 212 and the interface member 214. FIG. 16 also shows angle β and angle θ which are formed within the right channel 230 and the left channel 232 formed by the respective curvilinear side rails 226, 228. Angles β and θ are preferably acute, most preferably forty-five degrees. Thus, the cross-sectional geometry of corner system 210 when the interface member 214 is received by the corner bracket 212, as shown in FIG. 16, is that of an isosceles triangle.

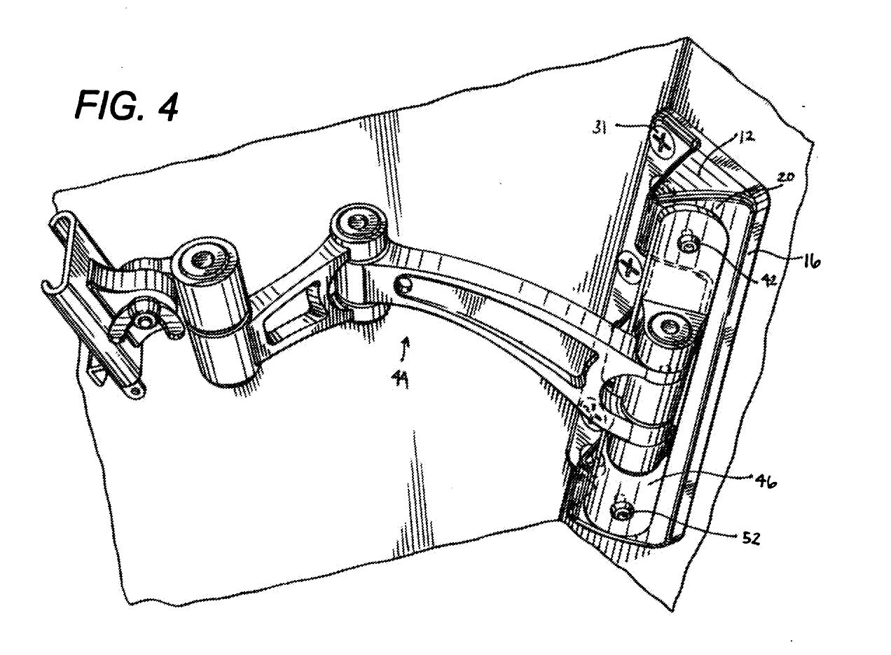

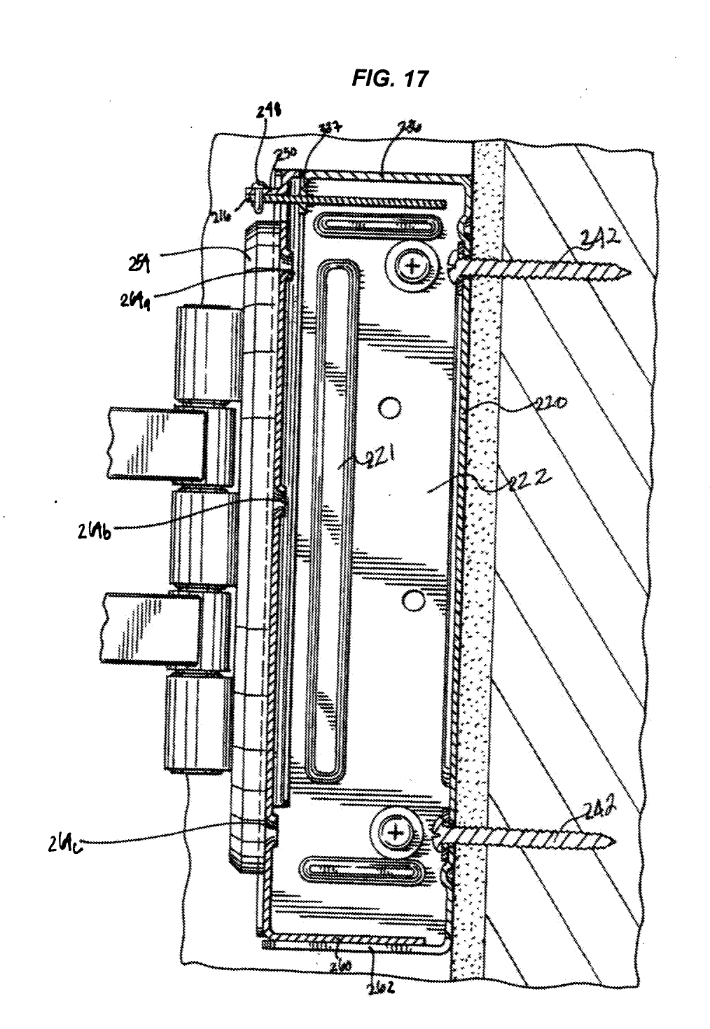

The interface member 214 includes a slot 238b which is aligned with the slot 238a of the securing tab 236 on the corner bracket 212. The securing member 216 is receivable by the slot 238b of the interface member 214. Because the slot 238b is aligned with the slot 238a of the securing tab 236, when the securing member 216 passes through slot 238b, it also passes through slot 238a. The securing member 216 may also include an opening 246a for reception of a fastener 248. The opening 246a of the securing member 216 is shown in FIG. 4. The interface member 214 may further include a protrusion 250 having an opening 246b. When the securing member 216 is inserted into the slot 238b, it should be positioned such that the opening 246a of the securing member 216 is aligned with the opening 246b of the protrusion. Thus, fastener 248 may pass through both openings 246a and 246b. This essentially locks the securing member 216 in place, and it secures the interface member 214 to the corner bracket 212. As shown in FIG. 17, the securing member 216, the protrusion 250 and the fastener 248 cooperate to secure the interface member 214 to the corner bracket 212. As shown in FIG. 13, the interface member 214 may include a transverse element, such as bottom plate 260, and the corner bracket 212 may include a cooperative transverse element, such as bottom wall 262. When the interface member 214 is fully inserted into the receiver 234, the bottom wall 262 abuts the bottom plate 260 and further secures the interface member 214 to the corner bracket 212.

The corner mount system 210 may include the support arm assembly 218 to join the flat screen display to the interface member 214. The support arm assembly 218 includes a connector 254, at least one support arm 256 and a flat screen display bracket 258. As shown in FIGS. 8 and 9, the connector 254 couples the securing arm assembly 218 to the interface member 214. As shown in FIG. 4, the interface plate includes an upper aperture 264a, a middle aperture 264b and a lower aperture 264c. These apertures 264a, 264b receive a fastener (not shown) to secure the connector 254 to the interface member 214.

In many conventional mounts, an apparatus is attached to a flat screen display, and then that apparatus must be mounted to a wall. This requires one operator to hold and elevate the flat screen display while the apparatus is mounted to the wall by a second operator. This can be a difficult job which often results in an incorrectly mounted flat screen display, e.g. a display that is installed at an angle and not horizontal to the floor. In addition, conventional wall mounts cannot be installed deep within a corner, especially at a corner seam, because the flat screen display and/or the mount components are too large and there is not enough clearance for a corner installation.

To attain the installed position shown in FIGS. 10, 17 and 18, the corner bracket 212 is first secured in the corner region A, without being connected to the interface member 214. The corner bracket 212 is secured at the seam A1 to one of walls A2, A3 with fasteners 242 extending into at least one of studs B1, B2. At the seam A1, a first fastener 242 extends through the right plate 220 and into the right stud B1, while a second fastener 242 extends through the left plate 222 and into the left stud B2. Consequently, the central edge 224 of the corner bracket 212 is adjacent the corner seam A1. Separately, the interface member 214 is coupled with the connector 254 of the support arm assembly 218 which is joined by the bracket 258 to the flat screen display D. Once the flat screen display D is joined to the support arm assembly 218, and the support arm assembly 218 is coupled to the interface member 214, the interface member 214 is connected to the corner bracket 212. To accomplish this, the lower portion of the interface member 214 is aligned with the upper portion of the bracket 212. Specifically, the interface member 214 is elevated above the bracket 212 such that the lower portion of the member rails 266, 268 are aligned with the upper portion of the bracket rails 226, 228. This alignment allows for sliding engagement by the receiver 224 as the interface member 214 slides downward along the height of the bracket 212, as shown in the intermediate positions of FIG. 9. The initial stage of sliding engagement occurs between the lower portion of the member rails 266, 268 and the upper portion of the bracket rails 226, 228, and then continues as the interface member 214 moves downward along the bracket 212. Next, the securing member 216 is utilized to secure the connection between the interface member 214 and the corner bracket 212.

In the installed position (see FIGS. 10, 17 and 18) line C1, which is a chord through connector 254, bisects angle α such that α1 and α2 are each forty-five degrees. Once the corner mount system 210 reaches the installed position, the support arm assembly 218, namely the connector 254, is aligned with line C1 such that they are not only parallel, but also collinear. Interface member 214 is perpendicular to line C1. In the installed position, the flat screen display, including the rear surface of the display, is positioned a considerable distance from both the corner seam A1 and the interface 214 and corner bracket 212. This distance is primarily a function of the support arm assembly 218, namely the length of the movable support arm 256.

While the specific embodiments have been illustrated and described, numerous modifications come to mind without significantly departing from the spirit of the invention, and the scope of protection is only limited by the scope of the accompanying Claims.

What is claimed is:

1. A corner mount system for mounting a flat screen display at a corner seam within a corner region, the corner mount system comprising:
a corner bracket having a right plate and a left plate which intersect to form a central edge that extends along a height of the corner bracket, wherein the right plate includes a right channel and the left plate includes a left channel, the corner bracket including at least one hole for reception of a fastener to secure the corner bracket to the corner region;
an elongated interface member having a right side rail and a left side rail; and,
wherein in an installed corner position, the corner bracket is securable at the corner seam and the interface member is brought into engagement with the corner bracket whereby the right side rail is slidingly received by the right channel and the left side rail is slidingly received by the left channel.

2. The corner mount system of claim 1, further comprising means for securing the corner bracket and the interface member in the installed position.

3. The corner mount system of claim 2, wherein securing means includes a tab that extends from one of either the left or right plate of the corner bracket to prevent upward movement of the interface member relative to the bracket.

4. The corner mount system of claim 3, wherein the securing means further includes a securing member that extends through a slot of the interface member and that is coupled to the tab.

5. The corner mount system of claim 1, further comprising a support arm assembly including a connector, a first arm and a flat screen display bracket, wherein the connector is secured to the interface member to couple the support arm assembly to the interface member.

6. The corner mount system of claim 1, wherein the interface member includes a bottom plate and the corner bracket includes a bottom wall, such that in the installed position the bottom wall abuts the bottom plate.

7. The corner mount system of claim 6, wherein the abutment of the bottom wall with the bottom plate retains the interface member within the receiver of the corner bracket.

8. The corner mount system of claim 1, wherein the right and left side rails of the interface member are curvilinear.

9. The corner mount system of claim 8, wherein the right and left channels of the corner bracket are curvilinear, whereby the right and left rails can be slidingly engaged by the right and left channels.

10. The corner mount system of claim 1, wherein the right and left channels define a receiver that receives the rails of the interface member.

11. The corner mount system of claim 1, wherein the right plate and the left plate of the bracket are integrally formed.

12. A corner mount system for mounting a flat screen display at a corner seam within a corner region, the corner mount system comprising:
a corner bracket having a right plate and a left plate which intersect to form a central edge that extends along a height of the corner bracket, wherein the right plate includes a right channel and the left plate includes a left channel, the corner bracket including at least one hole for reception of a fastener to secure the corner bracket to the corner region;
an elongated interface member having a right side rail and a left side rail; and,
a support arm assembly including a flat screen display bracket, a first arm and a connector secured to the interface member to couple the support arm assembly to the corner bracket in an installed position;
wherein in the installed corner position, the corner bracket is securable at the corner seam and the interface member is brought into engagement with the corner bracket whereby the right side rail is slidingly received by the right channel and the left side rail is slidingly received by the left channel.

13. The corner mount system of claim 12, further comprising means for securing the corner bracket and the interface member in the installed position.

14. The corner mount system of claim 13, wherein securing means includes a tab that extends from one of either the left or right plate of the corner bracket to prevent upward movement of the interface member relative to the bracket.

15. The corner mount system of claim 14, wherein the securing means further includes a securing member that extends through a slot of the interface member and that is coupled to the tab.

16. The corner mount system of claim 12, wherein the interface member includes a bottom plate and the corner bracket includes a bottom wall, such that in the installed position the bottom wall abuts the bottom plate.

17. The corner mount system of claim 16, wherein the abutment of the bottom wall with the bottom plate retains the interface member within the receiver of the corner bracket.

18. The corner mount system of claim 12, wherein the right and left side rails of the interface member are curvilinear, and wherein the right and left channels of the corner bracket are curvilinear, whereby the right and left rails are slidingly engaged by the right and left channels.

19. The corner mount system of claim 12, wherein the right and left channels define a receiver that receives the rails of the interface member.

20. A corner mount system for mounting a flat screen display at a corner region, the corner mount system comprising:
a bracket having a left portion with a left channel and a right portion with a right channel, the bracket also having a securing region with at least one hole for reception of a fastener to secure the bracket to the corner region;
an interface member having a left flange and a right flange, said flanges being in an opposed positional relationship, wherein the interface member is coupled to the bracket; and
a support arm assembly including a connector, a first arm and a flat screen display bracket, wherein the connector is connected to the interface member to couple the support arm assembly to the interface member and wall bracket.
